(19) United States
(12) Patent Application Publication
(10) Pub. No.: US 2007/0095562 A1
(43) Pub. Date: May 3, 2007

(54) Flexible circuit board with reinforcing board

(75) Inventor: Ching-Cheng Tsai, Taipei (TW)

Correspondence Address: BACON & THOMAS, PLLC, 625 SLATERS LANE, FOURTH FLOOR, ALEXANDRIA, VA, 22314, US

(73) Assignee: CHICONY ELECTRONICS CO. LTD, Taipei (TW)

(21) Appl. No.: 11/476,850

(22) Filed: Jun. 29, 2006

(30) Foreign Application Priority Data
Oct. 28, 2005 (TW) 94218673

(51) Int. Cl. H05K 1/00

(52) U.S. Cl. 174/254

(57) ABSTRACT

A flexible circuit board with a reinforcing board is provided, comprising: a flexible substrate, having an upper surface and a lower surface; and a reinforcing board disposed at a front end of the upper surface of the flexible substrate, wherein a part of the reinforcing board is combined with the upper surface of the flexible substrate.

### BACKGROUND OF THE INVENTION

1. Field of the Invention

The present invention relates to a flexible circuit board, especially to a flexible circuit board with reinforcing board.

2. Description of the Related Art

Owing to the coming of digital times, the dependency of people on the electronic products increases. To meet demands of current electronic products such as high speed, high performance and lightweight, flexible circuit boards have gradually been applied in various electronic products, such as notebook computer, mobile phone, digital camera, personal digital assistant, printer and CD-ROM, etc.

The flexible circuit board may be a FPC (Flexible Printed Circuit), a FFC (Flexible Flat Cable) or a thin film switch, which is not only used for electrical connection, but also for carrying chips or other electronic devices. For enabling the cooperation and communication between the chips and other electronic devices, as well as effectively protecting the fragile chips, various package technologies for chips are developed. For example, common wafer bonding technologies include wire bonding, flip-chip and tape automated bonding (TAB), etc. The tape automated bonding is used to bond a chip on a flexible circuit board. Since the flexible circuit board itself is bendable, making the subsequent assembly processes more flexible, and the application becomes more widespread.

FIG. 2 schematically illustrates a conventional flexible circuit board being inserted into a connector of a circuit board. A conventional flexible circuit board comprises a flexible substrate 21 having an upper surface 22 and a lower surface 23 and a reinforcing board 25 adhered to a front end of the upper surface 22 of the flexible substrate 21.

When an user applies a force on a rear end of the reinforcing board 25 by a finger (fingernail) or a flat tool to position the conventional flexible circuit board into the connector 24 of a circuit board 26, it may be inconvenient for assembly due to the small area on which the force is applied of the rear end of the reinforcing board 25. FIG. 3 illustrates a finger applying a force on a conventional flexible circuit board. Due to bad operation of the operator, the flexible substrate 21 may be bent down first to increase the area on which the force is applied of the rear end of the reinforcing board 25, such that it is easy for the operator to apply the force on the conventional flexible circuit board and position the conventional flexible circuit board into the connector 24. However, due to the property of the material of the flexible substrate 21, it is easy to break at the location, indicated by an arrow “a”, of the flexible substrate 21, resulting in an abnormal use of the conventional flexible circuit board.

FIG. 4 illustrates a finger applying a force on a conventional flexible circuit board. When a conventional flexible circuit board is being inserted into the connector 24, due to bad operation of the operator, the flexible substrate 21 may be bent upward first such that it is easy for the operator to apply the force on the conventional flexible circuit board and position the conventional flexible circuit board into the connector 24. However, due to the property of the material of the flexible substrate 21, it is easy to break at the location, indicated by an arrow “b”, of the flexible substrate 21, resulting in an abnormal use of the conventional flexible circuit board.

### SUMMARY OF THE INVENTION

One objective of the present invention is to provide a flexible circuit board with a reinforcing board, in which the reinforcing board can increase the height of the whole flexible substrate such that the assembly of the flexible circuit board and a connector can be accomplished by pushing the reinforcing board into the connector to cooperatively move the flexible substrate into the connector.

Another objective of the present invention is to provide a flexible circuit board with a reinforcing board, in which a part of the reinforcing board is combined with an upper surface of the flexible substrate to increase an area on which a force is applied of the reinforcing board, thereby preventing the flexible substrate from being broken due to bad operation of an operator.

For achieving the above objectives, the present invention provides a flexible circuit board with a reinforcing board comprising a flexible substrate having an upper surface and a lower surface and a reinforcing board disposed at the upper surface of the flexible substrate. A part of the reinforcing board is combined with the upper surface of the flexible substrate.

Preferably, the reinforcing board is an electrically insulator.

Preferably, the reinforcing board is a hard plastic material.

Preferably, the reinforcing board is disposed at a front end of the upper surface of the flexible substrate by adherence.

### BRIEF DESCRIPTION OF THE DRAWINGS

FIG. 1 is a schematic view depicting a flexible circuit board of the present invention is to be inserted into a connector of a circuit board.

FIG. 2 is a schematic view depicting a conventional flexible circuit board is to be inserted into a connector of a circuit board.

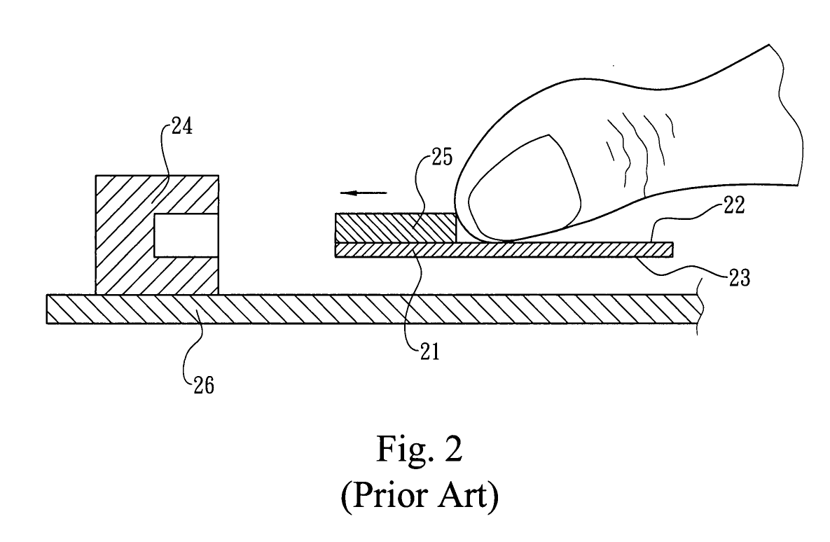

FIG. 3 illustrates a finger applying a force on a conventional flexible circuit board.

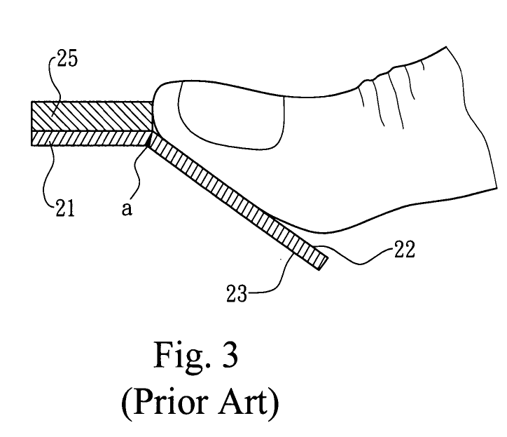

FIG. 4 illustrates a finger applying a force on a conventional flexible circuit board.

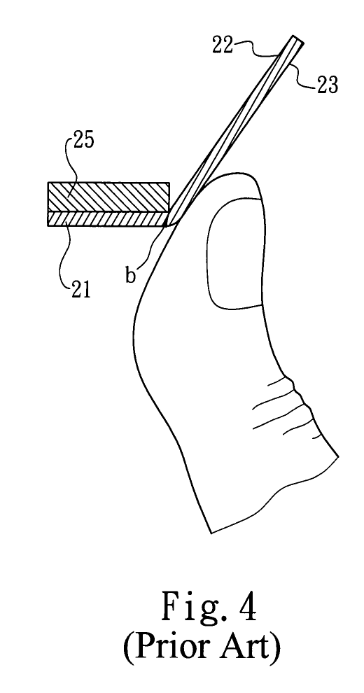

### DETAILED DESCRIPTION OF THE PREFERRED EMBODIMENTS

Although the present invention will be described in considerable detail with reference to certain preferred embodiments thereof, however prior to this description, it is should be understood that those skilled in the art can easily make changes to the present invention described herein and the same performance as the present invention is obtained. Therefore, it is to be understood that the following description is a general disclosure to those skilled in the art and is not restrictive of the present invention.

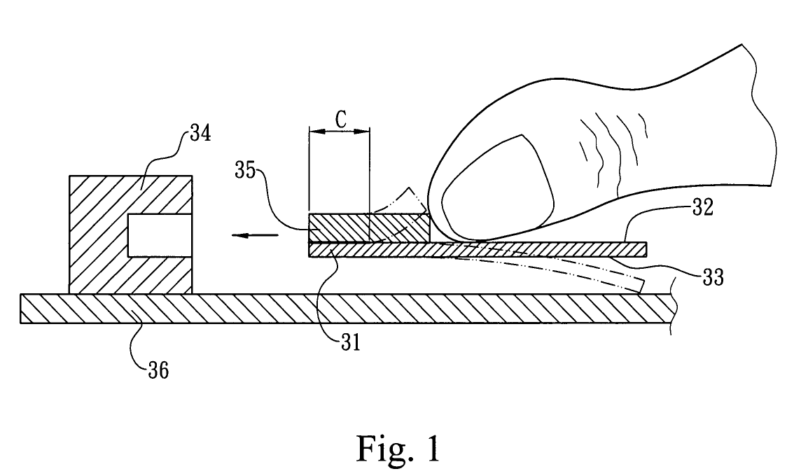

Referring to FIG. 1, which depicts a schematic view of a flexible circuit board of the present invention is to be inserted into a connector of a circuit board. The flexible circuit board according to the present invention comprises a flexible substrate 31 having an upper surface 32 and a lower surface 33 and a reinforcing board 35 disposed at a front end of the upper surface 32 of the flexible substrate 31. A front part of the reinforcing board 35 is combined with the upper surface 32 of the flexible substrate 31, i.e. a part of the reinforcing board 35 as indicated by the arrow “C” is strongly adhered to the front end of the upper surface 32 of the flexible substrate 31.

When a user applies a force on the reinforcing board 35 to insert the flexible circuit board into a connector 34 of a circuit board 36, due to that a rear part of the reinforcing board 35 can be moved away from the upper surface 32 of the flexible substrate 31, an area on which the force is applied of the rear part of the reinforcing board 35 is increased, and thus it is convenient for applying the force by the user. More importantly, the risk of the breakage of the flexible substrate 31 is avoided.

The advantage of the flexible circuit board of the present invention is as follows: a part of the reinforcing board is combined with the upper surface of the flexible substrate, and another part of the reinforcing board can be relatively moved away from the upper surface of the flexible substrate, such that the breakage of the flexible substrate due to the bad operation of the operator is avoided, i.e. the flexible substrate can be bent upward/downward.

Although the present invention has been described in considerable detail with reference to certain preferred embodiments thereof, those skilled in the art can easily understand that all kinds of alterations and changes can be made within the spirit and scope of the appended claims. Therefore, the spirit and scope of the appended claims should not be limited to the description of the preferred embodiments contained herein.

What is claimed is:

1. A flexible circuit board with a reinforcing board, comprising:
a flexible substrate, having an upper surface and a lower surface; and
a reinforcing board disposed at the upper surface of said flexible substrate, wherein a part of said reinforcing board is combined with said upper surface of said flexible substrate.

2. The flexible circuit board with a reinforcing board as claimed in claim 1, wherein said reinforcing board is an electrically insulator.

3. The flexible circuit board with a reinforcing board as claimed in claim 1, wherein said reinforcing board is a hard plastic material.

4. The flexible circuit board with a reinforcing board as claimed in claim 1, wherein said reinforcing board is combined with a front end of said upper surface of said flexible substrate by adherence.

5. A reinforcing board suitable for inserting into a connector of a circuit board, said flexible circuit board comprises a flexible substrate and a reinforcing board, characterized in that said reinforcing board is disposed at the upper surface of said flexible substrate, wherein a part of said reinforcing board is combined with the upper surface of said flexible substrate.

6. The reinforcing board as claimed in claim 5, wherein said reinforcing board is an electrically insulator.

7. The reinforcing board as claimed in claim 5, wherein said reinforcing board is a hard plastic material.

8. The reinforcing board as claimed in claim 5, wherein said reinforcing board is combined with a front end of the upper surface of said flexible substrate by adherence.
